(19) United States
(12) Patent Application Publication
(10) Pub. No.: US 2024/0351939 A1
(43) Pub. Date: Oct. 24, 2024

(54) SUBSTRATE FOR MOUNTING LED AND LED-MOUNTED SUBSTRATE

(71) Applicant: TAIYO HOLDINGS CO., LTD., Saitama-Ken (JP)

(72) Inventors: Meiten KOH, Saitama-ken (JP); Haruka ONODA, Saitama-ken (JP); Masayuki SHIMURA, Saitama-ken (JP); Kosuke NAKAJIMA, Saitama-ken (JP)

(21) Appl. No.: 18/291,005

(22) PCT Filed: Jul. 26, 2022
(86) PCT No.: PCT/JP2022/028766

§ 371 Date: Jan. 22, 2024

(30) Foreign Application Priority Data
Jul. 26, 2021 (JP) 2021-121900

(51) Int. Cl. C03C 17/00; C03C 17/32; H01L 25/13; H01L 33/60

(52) U.S. Cl. CPC C03C 17/009; C03C 17/007; C03C 17/32; H01L 25/13; H01L 33/60; C03C 2217/70

(57) ABSTRACT

Provided is a substrate for mounting an LED that can be applied to a thin base material and can result in a sufficient reflectance, particularly a substrate for mounting an LED, adaptable to a mini-LED and a μ-LED. In the substrate for mounting an LED, including a base material and a reflective layer that is layered on an upper region thereof, plural openings are disposed at generally equal spacings in longitudinal and lateral directions in the reflective layer, respectively, the reflective layer is the cured product of a curable resin composition including a curable resin and titanium oxide, the cured product has a storage elastic modulus of 4.0 GPa or less at 25° C., the spacings between the opening and the opening adjacent thereto in the longitudinal direction and the lateral direction are not less than twice the lengths of the opening in the longitudinal direction and the lateral direction, respectively, and the total area rate of the openings with respect to the area of the reflective layer is 0.1% or more and 9.0% or less.

### CROSS REFERENCE TO RELATED APPLICATIONS

This application is a 371 U.S. National Phase of International Application No. PCT/JP2022/028766, filed on Jul. 26, 2022, which claims priority to Japanese Patent Application No. 2021-121900, filed Jul. 26, 2021. The entire disclosures of the above applications are incorporated herein by reference.

### BACKGROUND OF THE INVENTION

### Field of the Invention

The present invention relates to a substrate for mounting an LED. Also, the present invention relates to an LED-mounted substrate in which an LED is mounted on the substrate for mounting an LED.

### Related Art

In recent years, light-emitting diodes (LEDs) have sprung into wide use as low-power-consumption, long-lasting light sources in response to a request to reduce the energy consumption of electric appliances. Such LEDs are used as the backlights of liquid crystal displays for portable terminals, personal computers, televisions, and the like, and the light sources of lighting fixtures, and the like. In such cases, the types of LEDs to be directly mounted on printed wiring boards coated with resist layers, so-called surface-mounted LEDs have been increasingly often used for slimming down of backlights. For increasing the reflectances of such surface-mounted LEDs, there appear to be examples in which the reflectances are increased by using reflectors or allowing resist layers to be white. However, it is necessary to allow substrates to be thinner than substrates used until now and to allow openings to be narrower in order to be adaptable to the downsizing of LEDS.

For example, Japanese Patent Laid-Open No. 2018-207048 discloses a flexible substrate for an LED element, including a metal wiring portion formed on a surface of a supporting substrate including a resin film having flexibility, wherein an insulative protective film is formed on the supporting substrate and the metal wiring portion, excluding a region for mounting an LED element, and the insulative protective film has a multilayered structure including: an intimate contact layer included in an intimate contact surface between the supporting substrate and the metal wiring portion; and a light reflection layer placed on the intimate contact layer so that the light reflection layer is exposed to a surface on which an LED element is mounted.

Japanese Patent Laid-Open No. 2018-207048 proposes a backlight using the flexible substrate in order to solve a problem in that a flexible substrate for an LED element is thinned. In Japanese Patent Laid-Open No. 2018-207048, the intimate contact layer is first formed, and the light reflection layer is then formed on a partial region thereof by coating. However, there has been a trade-off problem in that warpage of the substrate occurs when a region on which the light reflection layer is formed is allowed to be larger in order to improve reflectivity while the reflectivity deteriorates the region on which the light reflection layer is formed is allowed to be smaller in order to suppress the warpage.

Moreover, Japanese Patent Laid-Open No. 2018-207048 has had a problem in that the formation of the light reflection layer by the two-layer coating causes steps to be complicated, and a necessity to discretely form the upper layer causes the steps to be further complicated. Moreover, there has also been a problem in that an opening measuring 8 mm to 10 mm per side is required for mounting an LED measuring 3 mm per side, and it is impossible to form the light reflection layer in a gap between the opening and the LED, whereby the reflectivity deteriorates. In addition, in the case of a μ-LED, it is very difficult to narrow the gap to 50% or less of the opening in the two-layer coating in consideration of a deviation from each designed value of the intimate contact layer and the reflective layer due to ink bleeding when the gap between the opening and the LED is narrowed to increase the reflectivity. In consideration of the above, it is desirable to be able to form a reflective layer by one-layer coating.

Therefore, an objective of the present invention is to provide a substrate for mounting an LED that can be applied to a thin base material and can result in a sufficient reflectance, particularly a substrate for mounting an LED, adaptable to a mini-LED and a μ-LED. Moreover, an objective of the present invention is to provide an LED-mounted substrate including an LED mounted on the substrate for mounting an LED.

### SUMMARY

As a result of intensive research, the present inventors found that the problems described above can be solved by adjusting the storage elastic modulus of a cured product (reflective layer), and further adjusting a spacing between an opening and an opening adjacent thereto in a longitudinal direction or a lateral direction, the total area rate of openings with respect to the area of the reflective layer, and a distance between a side of each opening and a side of each LED in the longitudinal direction or the lateral direction in a case in which LEDs are mounted in the generally central regions of the openings, in a substrate for mounting an LED, the substrate including a base material and the reflective layer that is layered on the upper region thereof, wherein the plurality of openings are disposed at generally equal spacings in the longitudinal and lateral directions in the reflective layer, respectively. Thus, the present invention was accomplished.

In other words, a substrate for mounting an LED according to the present invention includes
a base material and a reflective layer that is layered on an upper region thereof, wherein
a plurality of openings are disposed at generally equal spacings in longitudinal and lateral directions in the reflective layer, respectively,
the reflective layer is a cured product of a curable resin composition including a curable resin and titanium oxide,
the cured product has a storage elastic modulus of 4.0 GPa or less at 25° C.,
the spacings between the opening and the opening adjacent thereto in the longitudinal direction and the lateral direction are not less than twice the lengths of the opening in the longitudinal direction and the lateral direction, respectively, and
a total area rate of the openings with respect to an area of the reflective layer is 0.1% or more and 9.0% or less.

In an aspect of the present invention, it is preferable that the lengths of the openings of the reflective layer are 3.0 mm or less in the longitudinal direction and 4.0 mm or less in the lateral direction.

In an aspect of the present invention, it is preferable that the lengths of the openings of the reflective layer are 1.5 mm or less in the longitudinal direction and 1.5 mm or less in the lateral direction.

In an aspect of the present invention, it is preferable that the base material has a thickness of 3.0 mm or less.

In an aspect of the present invention, it is preferable that the base material has a thickness of 1.0 mm or less.

In an aspect of the present invention, it is preferable that a designed value of each of the openings has a deviation of less than 0.2 mm and more than −0.2 mm.

In an aspect of the present invention, it is preferable that the spacings between the opening and the opening adjacent thereto in the longitudinal direction and the lateral direction are not less than four times the lengths of the opening in the longitudinal direction and the lateral direction, respectively.

It is preferable that an LED-mounted substrate according to another aspect of the present invention includes LEDs mounted in generally central regions of the openings of the substrate for mounting an LED.

### Advantageous Effects of Invention

In accordance with the present invention, there can be provided a substrate for mounting an LED that can be applied to a thin base material and can result in a sufficient reflectance, particularly a substrate for mounting an LED, adaptable to a mini-LED and a μ-LED. Moreover, in accordance with the present invention, there can be provided an LED-mounted substrate including an LED mounted on the substrate for mounting an LED.

### BRIEF DESCRIPTION OF THE DRAWINGS

FIG. 1 is a schematic cross-sectional view of a substrate for mounting an LED of the present invention.

FIG. 2 is a schematic top view of the substrate for mounting an LED of the present invention.

FIG. 3 is a schematic cross-sectional view of an LED-mounted substrate of the present invention.

FIG. 4 is a schematic top view of the LED-mounted substrate of the present invention.

FIG. 5 is a schematic top view of the various shapes of openings on an LED-mounted substrate of the present invention.

### DETAILED DESCRIPTION

### [Substrate for Mounting LED]

A substrate for mounting an LED according to the present invention includes a base material and a reflective layer that is layered on the upper region thereof, wherein the reflective layer includes a cured product of a curable resin composition described below.

The storage elastic modulus of the cured product of the curable resin composition at 25° C. is 4.0 GPa or less, preferably 3.8 GPa or less, more preferably 3.6 GPa or less, and still more preferably 3.4 GPa or less. The lower limit value thereof is preferably 0.1 GPa or more, more preferably 0.5 GPa or more, and still more preferably 1.0 GPa or more when being set. Measurement of the storage elastic modulus is as follows. In other words, the curable resin composition is printed on the base material by screen printing so that the film thickness of the curable resin composition that have been cured is 20 μm or more and 50 μm or less. The cured product produced by the curing is peeled from the base material, and cut into a piece of 5±0.3 mm×50+5 mm. Measurement of the cut piece is performed using a dynamic viscoelasticity measurement apparatus (DMA, model number: RSA-G2, manufactured by TA Instruments Japan Inc.) under conditions of a measured temperature of 25 to 300° C., a temperature-raising rate of 5° C./min, a loading gap of 10 mm, a frequency of 1 Hz, and an axial force (axial tension) of 0.05 N, and a storage elastic modulus value at 25° C. in the measurement is regarded as a measured value. In a case in which the storage elastic modulus is within the numerical range described above, occurrence of warpage is suppressed even in the base material on which the reflective layer has been formed, and the base material can have hardness effective as a resist film, is inhibited from being recessed when an external force is applied, and is inhibited from being dented when being transported and handled. Here, the warpage of the substrate is represented by the total value of the heights of the four corners of the substrate, rising from a desk, after the formation of the reflective layer. The warpage of the substrate is preferably 3 mm or less, and more preferably 2 mm or less.

In the substrate for mounting an LED according to the present invention, a plurality of openings are disposed at generally equal spacings in longitudinal and lateral directions in the reflective layer, respectively. The generally equal spacings mean equal spacings based on designed values, and are the equal spacings including tolerated deviations caused by tolerances and variations in a production step. In the present invention, the longitudinal and lateral directions on the substrate are defined as follows. The lateral direction is defined as a direction parallel to a long side, having the longest measured length, of an opening, and the longitudinal direction is defined as a direction parallel to a short side orthogonal to the lateral direction. When the lengths of sides are equal to each other, one side is regarded as a long side, and a side orthogonal to the long side is regarded as a short side. The shape of such an opening, viewed from above, is not particularly limited. Examples thereof include: quadrangular shapes such as square, rectangular, and trapezoidal shapes; polygonal shapes; oval shapes; and circular shapes. Such quadrangular shapes are preferred. The quadrangular shapes may also be shapes with round corners (rounded-corner quadrangular shapes).

In the substrate for mounting an LED according to the present invention, the spacings between the opening and the opening adjacent thereto in the longitudinal direction and the lateral direction are not less than twice, preferably 4 times or more, more preferably 4 times or more and 20 times or less, and still more preferably 5 times or more and 10 times or less the lengths of the opening in the longitudinal direction and the lateral direction, respectively. The spacing between the opening and the opening adjacent thereto in the longitudinal direction or the lateral direction satisfies such a condition, whereby the deviations of the openings from a design value are inhibited to inhibit occurrence of trouble when a large number of openings are disposed so that a large number of LEDs can be mounted.

In the substrate for mounting an LED according to the present invention, the longitudinal length of each opening is preferably 3.0 mm or less, more preferably 2.0 mm or less, and still more preferably 1.5 mm or less, and the lateral length thereof is preferably 4.0 mm or less, more preferably is 2.0 mm or less, and still more preferably 1.5 mm or less. The longitudinal and lateral lengths of each opening satisfy such a condition, whereby a large number of openings can be disposed so that a large number of mini-LEDs and μ-LEDs can be mounted.

In the substrate for mounting an LED according to the present invention, the total area rate of the openings with respect to the area of the reflective layer is 0.1% or more and 9.0% or less, preferably 0.5% or more and 8.5% or less, and more preferably 1.0% or more and 5.0% or less. The total area rate of the openings with respect to the area of the reflective layer satisfies the condition described above, whereby the area of the reflective layer can be increased to improve a reflectance. In particular, the white reflective layer results in excellent reflectivity, and can be therefore preferably used for mounting an LED. A method of measuring a reflectance is as follows. In other words, the curable resin composition is printed on the base material by screen printing so that the film thickness of the cured curable resin composition is 30 μm, and the Y value in the XYZ color specification method, of the cured product produced by the curing, measured by an SCI method using a spectral colorimeter (model number: CM-2600d, manufactured by KONICA MINOLTA, INC.) is regarded as the measured value of the reflectance.

In the substrate for mounting an LED according to the present invention, the deviation of each opening from the designed value is preferably less than 0.2 mm and more than −0.2 mm, and more preferably 0.15 mm or less and −0.15 mm or more. In the present invention, a deviation means that the position of an actually formed reflective layer deviates from a designed value, is a phenomenon in which, for example, a reflective layer is formed up to a position closer to the innermost area of an opening than a designed value due to bleeding or the like, or a reflective layer is formed only up to a position closer to the outermost area of an opening than a designed value due to crawling of ink, and can be measured by microscopic observation of a reflective layer. The deviation of the reflective layer satisfies the condition described above, whereby the shape of each opening is formed according to the designed value, and therefore, trouble is inhibited in the case of mounting an LED.

In the substrate for mounting an LED according to the present invention, the rate of the reflective layer peeling from the base material in a crosscut test is preferably 20% or less, more preferably 10% or less, still more preferably 5% or less, and even more preferably 1%. The crosscut test can be conducted according to JISK5600-5-6. If the result of the crosscut test is within the range described above, an intimate contact property between the base material and the reflective layer becomes favorable.

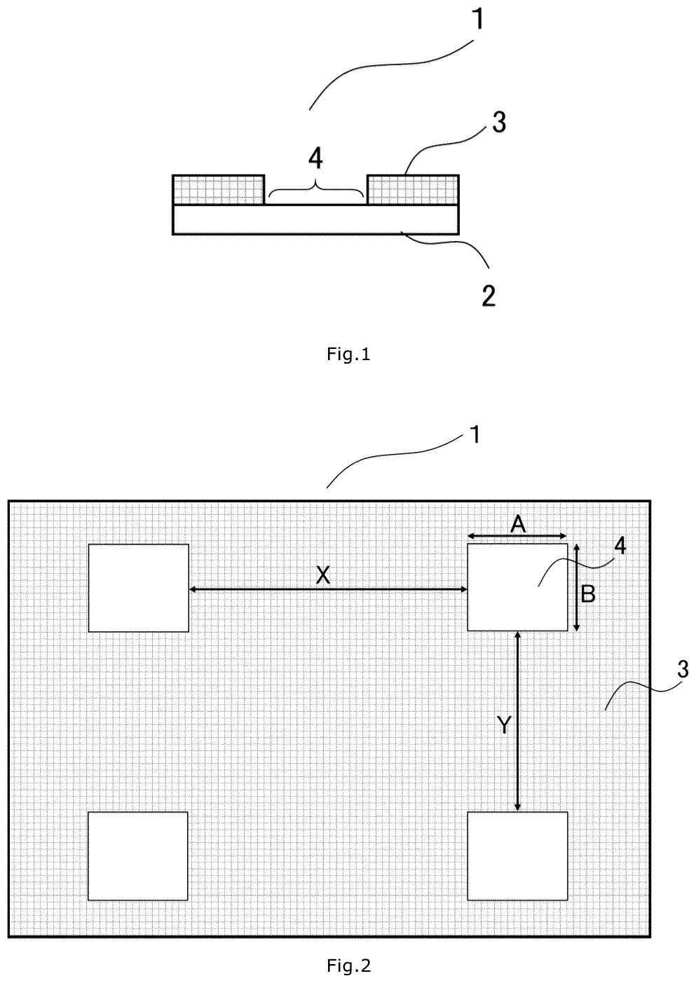

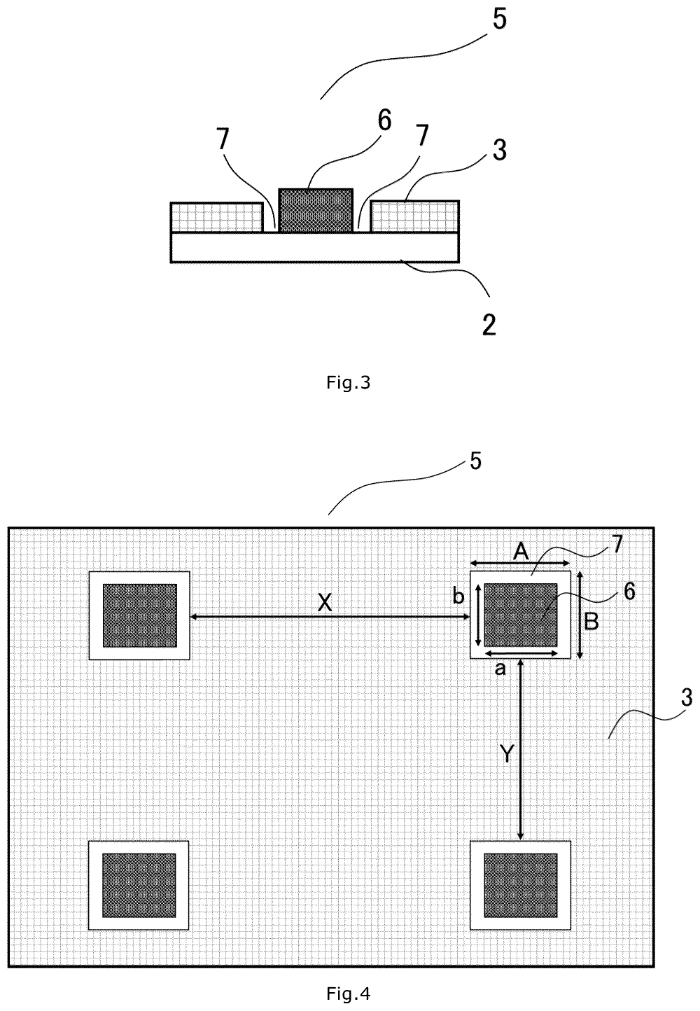

The substrate for mounting an LED according to the present invention is described with reference to the drawings. FIG. 1 illustrates a schematic cross-sectional view of a substrate for mounting an LED. The substrate 1 for mounting an LED illustrated in FIG. 1 includes a base material 2 and a reflective layer 3 that is layered on the upper region thereof. Openings 4 for mounting LEDs are disposed in the reflective layer 3. FIG. 2 illustrates a schematic top view of the substrate for mounting an LED. In the reflective layer 3 of the substrate 1 for mounting an LED illustrated in FIG. 2, the plurality of openings 4 for mounting LEDs are disposed at generally equal spacings in longitudinal and lateral directions, respectively. Here, the length of each opening in the lateral direction is indicated by A, the length of each opening in the longitudinal direction is indicated by B, a spacing between the opening and the opening adjacent thereto in the longitudinal direction is indicated by X, and a spacing between the opening and the opening adjacent thereto in the lateral direction is indicated by Y.

Further, an LED-mounted substrate including LEDs mounted in the generally central regions of the openings of the substrate for mounting an LED according to the present invention is described with reference to the drawings. FIG. 3 is a schematic cross-sectional view of the LED-mounted substrate. The LED-mounted substrate 5 illustrated in FIG. 3 includes the base material 2 and the reflective layer 3 that is layered on the upper region thereof. The LEDs 6 are mounted in the generally central regions of the openings of the reflective layer 3. Gaps 7 are present between the reflective layer 3 and the LEDs 6. FIG. 4 illustrates a schematic top view of the LED-mounted substrate. The LEDs 6 are mounted in the generally central regions of the plurality of openings 4 of the reflective layer 3 of the LED-mounted substrate 5 illustrated in FIG. 4. The gaps 7 are present between the reflective layer 3 and the LEDs 6. Here, the length of each opening in the lateral direction is indicated by A, the length of each opening in the longitudinal direction is indicated by B, the length of each LED in the lateral direction is indicated by a, the length of each LED in the longitudinal direction is indicated by b, a spacing between the opening and the opening adjacent thereto in the longitudinal direction is indicated by X, and a spacing between the opening and the opening adjacent thereto in the lateral direction is indicated by Y. When the LEDs 6 are mounted in the generally central regions of the openings 4, a distance between a side of each opening and a side of each LED in the lateral direction can be calculated as (A−a). A distance between a side of each opening and a side of each LED in the longitudinal direction can be calculated as (B−b). The area of each gap can be calculated as (A×B−a×b).

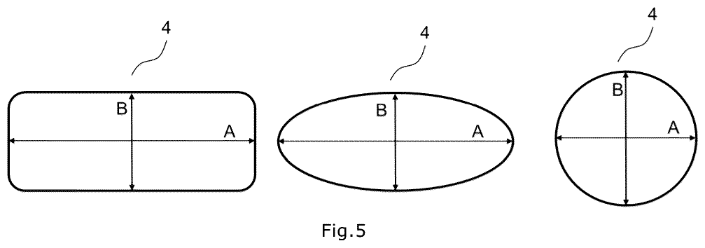

In FIGS. 1 to 4, the shape of each opening, viewed from above, is a quadrangular shape. However, the shape of each opening, viewed from above, may be another shape such as a rounded-corner quadrangular shape, an oval shape, or a circular shape, as illustrated in FIG. 5.

### [Curable Resin Composition]

The curable resin composition includes at least a resin and titanium oxide, and may further include another component. The curable resin composition enables formation of a cured product excellent in a balance between reflectivity and warpage, and is therefore preferred for use in a reflective layer that is directly formed on the insulating substrate of a printed wiring board. In particular, a white reflective layer is desired for enhancing the reflectivity of the cured product. Each component included in the curable resin composition is described below.

### [Resin]

The resin can be used without particular limitation as long as the cured product of the curable resin composition has a storage elastic modulus satisfying the condition described above at 25° C. The resin may be any of a thermosetting resin contributing to a thermal curing reaction by heating, a photo-curable resin contributing to a photo-curing reaction by light irradiation, and a photo-curable thermosetting resin contributing to both reactions.

Examples of the resin include fluorine resins, isocyanate compounds, blocked isocyanate compounds, epoxy resins, amino resins, polyfunctional oxetane compounds, benzoxazine resins, carbodiimide resins, cyclocarbonate compounds, and episulfide resins. These may be used singly, or in combination of two or more kinds thereof. Especially, fluorine resins and blocked isocyanate compounds are preferred.

### (Fluorine Resin)

Such a fluorine resin can be used without limitation as long as the fluorine resin includes a hydroxy group. The fluorine resin preferably has no chloro group from the viewpoint of a decrease in the reflectivity of the cured product of the curable resin composition and an increase in the number of impurities.

A copolymer of a vinyl monomer including fluorine and a vinyl monomer including a hydroxy group, or a hydrolysate of a copolymer of a vinyl monomer including fluorine and a vinyl ester monomer can be preferably used as the fluorine resin including a hydroxy group. Such fluorine resins including hydroxy groups may be used singly, or in combination of two or more kinds thereof.

Examples of the vinyl monomer including fluorine includes tetrafluoroethylene, hexafluoropropylene, and trifluoroethylene. The monomer including fluorine preferably has no chloro group from the viewpoint of a decrease in the reflectivity of the cured product of the curable resin composition and an increase in the number of impurities, and is particularly preferably tetrafluoroethylene. Such monomers including fluorine may be used singly, or in combination of two or more kinds thereof.

Examples of the vinyl monomers including hydroxy groups include: vinyl ethers including hydroxy groups, such as 2-hydroxyethylvinylether, 3-hydroxypropylvinylether, 2-hydroxypropylvinylether, 2-hydroxy-2-4-hydroxy-2-methylpropylvinylether, 4-hydroxybutylvinylether, methylbutylvinylether, 5-hydroxypentylvinylether, and 6-hydroxyhexylvinylether; allyl ethers including hydroxy groups, such as 2-hydroxyethylallylether, 4-hydroxybutylallylether, and glycerol monoallyl ether; and vinyl alcohols. These monomers including hydroxy groups may be used singly, or in combination of two or more kinds thereof. Examples of the vinyl ester monomer include vinyl acetate, vinyl propionate, and vinyl formate.

The amount of blended fluorine resin is preferably 10% by mass or more and 50% by mass or less, more preferably 15% by mass or more and 45% by mass or less, and still more preferably 18% by mass or more and 35% by mass or less on a solid content basis with respect to the curable resin composition. The amount of blended fluorine resin is within the range described above, whereby a cured product excellent in heat resistance can be obtained.

### (Isocyanate Compound)

Such an isocyanate compound can be used without particular limitation as long as the isocyanate compound includes two or more isocyanate groups. The isocyanate compound reacts with the fluorine resin described above to form a urethane bond and to become a cured product. In particular, the isocyanate compound preferably includes a chain alkyl group or a group including at least any one of an ether group and a silicate group.

A polyisocyanate compound can be blended as the isocyanate compound. Examples of the polyisocyanate compound include: aromatic polyisocyanates such as 4,4′-diphenylmethanediisocyanate, 2,4-tolylenediisocyanate, 2,6-tolylenediisocyanate, naphthalene-1,5-diisocyanate, o-xylylenediisocyanate, m-xylylenediisocyanate, and 2,4-tolylene dimer; aliphatic polyisocyanates such as tetramethylene diisocyanate, hexamethylene diisocyanate, methylene diisocyanate, trimethylhexamethylene diisocyanate, 4,4-methylenebis(cyclohexyl isocyanate), and isophorone diisocyanate; alicyclic polyisocyanates such as bicycloheptane triisocyanate; and adduct forms, biuret forms, and isocyanurate forms of the isocyanate compounds mentioned above. The isocyanate compounds may be used singly, or in combination of two or more kinds thereof.

In the present invention, the isocyanate compound is preferably a blocked isocyanate compound in view of improvement in workability due to excellent storage stability.

An addition reaction product of an isocyanate compound and an isocyanate blocking agent can be used as the blocked isocyanate compound. Examples of isocyanate compounds that can react with the isocyanate blocking agent include the polyisocyanate compounds described above. Examples of the isocyanate blocking agent include: phenol-based blocking agents such as phenol, cresol, xylenol, chlorophenol, and ethylphenol; lactam-based blocking agents such as ε-caprolactam, δ-valerolactam, γ-butyrolactam, and β-propiolactam; active methylene-based blocking agents such as ethyl acetoacetate and acetylacetone; alcohol-based blocking agents such as methanol, ethanol, propanol, butanol, amyl alcohol, ethylene glycol monomethyl ether, ethylene glycol monoethyl ether, ethylene glycol monobutyl ether, diethylene glycol monomethyl ether, propylene glycol monomethyl ether, benzyl ether, methyl glycolate, butyl glycolate, diacetone alcohol, methyl lactate, and ethyl lactate; oxime-based blocking agents such as formaldehydeoxime, acetaldoxime, acetoxime, methyl ethyl ketoxime, diacetyl monooxime, and cyclohexane oxime; mercaptan-based blocking agents such as butyl mercaptan, hexyl mercaptan, t-butyl mercaptan, thiophenol, methyl thiophenol, and ethyl thiophenol; acid amide-based blocking agents such as acetic acid amide and benzamide; imide-based blocking agents such as succinic acid imide and maleic acid imide; amine-based blocking agents such as xylidine, aniline, butylamine, and dibutylamine; imidazole-based blocking agent such as imidazole and 2-ethylimidazole; imine-based blocking agents such as methyleneimine and propyleneimine; pyrazole-based blocking agents such as dimethylpyrazole; and maleate-based blocking agents such as diethyl maleate.

Examples of commercially available blocked isocyanate compounds may include: Desmodur (registered trademark) BL-3175, BL-4265, BL-1100/1, BL-1265/1, TPLS-2957, TPLS-2062, TPLS-2078, and TPLS-2117; DESMOTHERM 2170 and DESMOTHERM 2265 (both of which are manufactured by Sumitomo Bayer Urethane Co., Ltd.); CORONATE (registered trademark) 2512, CORONATE 2513, and CORONATE 2520 (all of which are manufactured by Tosoh Corporation); B-830, B-815, B-846, B-870, B-874, and B-882 (all of which are manufactured by MITSUI CHEMICALS POLYURETHANES, INC.); DURANATE SBN-70D, TPA-B80E, 17B-60P, and E402-B80B (all of which are manufactured by Asahi Kasei Corp.); and TRIXENE BI 7982, TRIXENE BI 7950, TRIXENE BI 7951, TRIXENE BI 7960, and TRIXENE BI 7961 (manufactured by Baxeneden Chemicals Limited). Especially, DURANATE SBN-70D and TRIXENE BI 7982 are preferred. Desmodur BL-3175 and BL-4265 are obtained using methylethyloxime as a blocking agent.

In the present invention, when the resin includes a fluorine resin and an isocyanate compound, the mass ratio of the fluorine resin to the isocyanate compound is 1 or more and 20 or less, preferably 2 or more and 10 or less, on a solid content basis. When the mass ratio of the fluorine resin to the isocyanate compound is within the numerical range described above, a cured product excellent in heat resistance can be obtained by curing reaction with the fluorine resin.

### [Titanium Oxide]

Examples of titanium oxide include rutile type titanium oxide and anatase type titanium oxide. It is preferable to use rutile type titanium oxide in the present invention. Anatase type titanium oxide which is the same kind of titanium oxide has higher whiteness than rutile type titanium oxide, and is commonly used as a white coloring agent. However, anatase type titanium oxide has photocatalyst activity, and may therefore cause discoloration of a resin in a resin layer due to light particularly irradiated from an LED. In contrast, rutile type titanium oxide is slightly inferior in whiteness to anatase type; however, the rutile type titanium oxide has almost no photoactivity, therefore results in prominently suppressed degradation (yellowing) of a resin by light due to the photoactivity of titanium oxide, and is also stable against heat. Therefore, a high reflectance can be maintained for a long period in a case in which the rutile type titanium oxide is used as a white coloring agent in the resin layer of a printed wiring board on which an LED is mounted.

Known rutile type titanium oxide can be used. Examples of methods of producing rutile type titanium oxide include two production methods which are a sulfuric acid method and a chlorine method. In the present invention, rutile type titanium oxide produced by any of the production methods can be preferably used. Here, the sulfuric acid method refers to a production method in which ilmenite ore or titanium slag as a raw material is dissolved in concentrated sulfuric acid to separate iron as ferrous sulfate, the solution is hydrolyzed to obtain a sediment of a hydroxide, and the sediment is burnt at high temperature to obtain rutile type titanium oxide. The chlorine method refers to a production method in which synthetic rutile or natural rutile as a raw material is allowed to react with chlorine gas and carbon at a high temperature of about 1000° C. to synthesize titanium tetrachloride, which is oxidized to obtain rutile type titanium oxide. Especially, rutile type titanium oxide produced by the chlorine method particularly prominently has an effect of suppressing the degradation (yellowing) of a resin due to heat, and is more preferably used in the present invention.

Titanium oxide of which the surface is treated with hydrous alumina, aluminum hydroxide, and/or a silicon dioxide may be used as the rutile type titanium oxide. Dispersibility in the curable resin composition, storage stability, flame resistance, and/or the like can be improved by using the surface-treated rutile type titanium oxide.

The average particle diameter of rutile type titanium oxide is preferably 0.1 μm or more and 1.0 μm or less, and more preferably 0.2 μm or more and 0.8 μm or less. In particular, 1% or more of rutile type titanium oxide having a particle diameter of 0.25 μm is preferably included with respect to the total of particles. Herein, the average particle diameter of rutile type titanium oxide is the average particle diameter (D50) which is the average of particle diameters including not only the particle diameters of primary particles but also the particle diameters of secondary particles (aggregates), and is a value of D50 measured by a laser diffraction method. Examples of measurement apparatuses used in the laser diffraction method include Microtrac MT3300EXII manufactured by MicrotracBEL Corp.

Commercially available rutile type titanium oxide can also be used. For example, TIPAQUE R-820, TIPAQUE R-830, TIPAQUE R-930, TIPAQUE R-550, TIPAQUE R-630, TIPAQUE R-680, TIPAQUE R-670, TIPAQUE R-680, TIPAQUE R-670, TIPAQUE R-780, TIPAQUE R-850, TIPAQUE CR-50, TIPAQUE CR-57, TIPAQUE CR-80, TIPAQUE CR-90, TIPAQUE 90-2, TIPAQUE CR-93, TIPAQUE CR-95, TIPAQUE CR-97, TIPAQUE CR-63, TIPAQUE CR-58, and TIPAQUE UT771 (manufactured by ISHIHARA SANGYO KAISHA, LTD.), Ti-Pure R-101, Ti-Pure R-103, Ti-Pure R-104, Ti-Pure R-105, Ti-Pure R-108, Ti-Pure R-900, Ti-Pure R-902+, Ti-Pure R-960, and Ti-Pure R-706 (manufactured by DuPont de Nemours, Inc.), TITONE R-25, R-21, R-32, R-7E, R-5N, R-62N, R-42, R-45M, GTR-100, and D-918 (manufactured by SAKAI CHEMICAL INDUSTRY CO., LTD.), and the like can be used as commercially available rutile type titanium oxides.

In the present invention, in a case in which the resin includes a fluorine resin, the mass ratio of rutile type titanium oxide to the fluorine resin is 1.4 or more and 4 or less, preferably 1.8 or more and 3.5 or less, with respect to the fluorine resin on a solid content basis. In a case in which the mass ratio of rutile type titanium oxide to the fluorine resin is within the numerical range described above, the resin layer having a high reflectance can be obtained.

### [Other Components]

### (Silica)

Known silica that can be used as a filler for use in an electronic material is acceptable. Silicas may be used singly, or in combination of two or more kinds thereof.

Examples of silicas include fused silica, spherical silica, amorphous silica, crystalline silica, and pulverizing silica. Of these, spherical silica is preferred from the viewpoint of the flowability of the curable resin composition. The shape of the spherical silica may be a spherical shape, and is not limited to a true-spherical shape.

The average particle diameter of silica is 0.01 μm or more and 10 μm or less, preferably 0.05 μm or more and 5 μm or less. Herein, the average particle diameter of silica can be measured in a manner similar to that in the case of the average particle diameter of the titanium oxide described above.

As the silica, either silica that has not been surface-treated or surface-treated silica can be used. In the present invention, surface-treated silica is preferably used from the viewpoint of the flowability of the curable resin composition. In such surface treatment of silica, the silica may be surface-treated in a composition in which silica in a state in which the silica has been surface-treated in advance is blended or silica as an article that has not been surface-treated and a surface treatment agent are separately blended. The surface treatment agent is not particularly limited, a known surface treatment agent may be used, and a surface treatment agent having a curable reactive group, for example, a coupling agent having a curable reactive group as an organic group, or the like is preferably used.

A coupling agent based on silane, titanate, aluminate, zircoaluminate, or the like can be used as the coupling agent. Especially, a silane-based coupling agent is preferred. Examples of such silane-based coupling agents may include vinyltrimethoxysilane, N-(2-aminomethyl)-3-vinyltriethoxysilane, aminopropylmethyldimethoxysilane, N-(2-aminoethyl)-3-aminopropyltrimethoxysilane, 3-aminopropyltriethoxysilane, 3-anilinopropyltrimethoxysilane, 3-glycidoxypropyltrimethoxysilane, 3-glycidoxypropylmethyldimethoxysilane, 2-(3,4-epoxycyclohexyl)ethyltrimethoxysilane, 3-methacryloxypropyltrimethoxysilane, and 3-mercaptopropyltrimethoxysilane. These may be used singly, or in combination. The amount of such a treated silane-based coupling agent is preferably 0.5 to 10 parts by mass with respect to 100 parts by mass of silica. In the present invention, a reactive functional group derived from the coupling agent applied to the silica is not included in a compound having a photo-curable reactive group or a thermosetting functional group.

The amount of blended silica is preferably 1% by mass or more and 20% by mass or less, more preferably 2% by mass or more and 15% by mass or less, and still more preferably 3% by mass or more and 10% by mass or less in a solid content basis with respect to the curable resin composition. The amount of blended silica is within the range described above, whereby the reflectance of the resin layer can be improved. Silica is not particularly essential, and may be blended when an advantageous effect can be confirmed, for example, an effect of improving a reflectance is seen.

### (Heat-Curing Catalyst)

The curable resin composition can be blended with a heat-curing catalyst. Examples of the heat-curing catalyst include: imidazole derivatives such as imidazole, 2-methylimidazole, 2-ethylimidazole, 2-ethyl-4-methylimidazole, 2-phenylimidazole, 4-phenylimidazole, 1-cyanoethyl-2-phenylimidazole, and 1-(2-cyanoethyl)-2-ethyl-4-methylimidazole; amine such compounds as dicyandiamide, benzyldimethylamine, 4-(dimethylamino)-N,N-dimethylbenzylamine, 4-methoxy-N,N-dimethylbenzylamine, and 4-methyl-N,N-dimethylbenzylamine; hydrazine compounds such as adipic acid dihydrazide and sebacic acid dihydrazide; and phosphorus compounds such as triphenyl phosphine. Examples of commercially available products thereof include: 2MZ-A, 2MZ-OK, 2PHZ, 2P4BHZ, and 2P4MHZ (all of which are the trade names of imidazole-based compounds) manufactured by SHIKOKU CHEMICALS CORPORATION; U-CAT 3513N (trade name of a dimethylamine-based compound) manufactured by San-Apro Ltd.; and DBU, DBN, and U-CAT SA 102 (all of which are bicyclic amidine compounds and salts thereof). Guanamine, acetoguanamine, benzoguanamine, melamine, and S-triazine derivatives such as 2,4-diamino-6-methacryloyloxyethyl-S-triazine, 2-vinyl-2,4-diamino-S-triazine, 2-vinyl-4,6-diamino-S-triazine/isocyanuric acid adduct, and 2,4-diamino-6-methacryloyloxyethyl-S-triazine/isocyanuric acid adduct can also be used, and these compounds that also function as agents for imparting intimate contact properties are preferably used in combination with heat-curing catalysts. The heat-curing catalysts may be used singly, or in combination of two or more kinds thereof.

The amount of blended heat-curing catalyst is preferably 0.1 to 5 parts by mass, more preferably 1 to 3 parts by mass, on a solid content basis with respect to the total amount of the curable resin composition.

### (Organic Solvent)

The curable resin composition can be allowed to contain an organic solvent for the purpose of, for example, adjusting viscosity in the cases of preparing the composition and coating a substrate or a film. A known common organic solvent such as: a ketone such as methyl ethyl ketone or cyclohexanone; an aromatic hydrocarbon such as toluene, xylene, or tetramethylbenzene; a glycol ether such as cellosolve, methyl cellosolve, butyl cellosolve, carbitol, methyl carbitol, butyl carbitol, propylene glycol monomethyl ether, dipropylene glycol monomethyl ether, dipropylene glycol diethyl ether, diethylene glycol monomethyl ether acetate, or tripropylene glycol monomethyl ether; an ester such as ethyl acetate, butyl acetate, butyl lactate, cellosolve acetate, butyl cellosolve acetate, diethylene glycol monoethyl ether acetate, butyl carbitol acetate, propylene glycol monomethyl ether acetate, dipropylene glycol monomethyl ether acetate, or propylene carbonate; an aliphatic hydrocarbon such as octane or decane; or a petroleum-based solvent such as petroleum ether, petroleum naphtha, or solvent naphtha can be used as the organic solvent. Especially, esters are preferred, and diethylene glycol monoethyl ether acetate is more preferred, in view of resulting in the lower gloss level of a formed cured coating because oil absorption of the curable resin composition easily occurs in a silica surface in the case of curing and drying when a porous material such as amorphous silica is used. These organic solvents may be used singly, or in combination of two or more kinds thereof.

The amount of blended organic solvent is not particularly limited, and can be appropriately set according to viscosity of interest to allow easy preparation of the curable resin composition. The viscosity of the curable resin composition can be appropriately adjusted depending on a printing method and a printing plate. It is preferable that the viscosity is around 50 dPas to 800 dPas, preferably 100 dPas to 500 dPas, in the case of screen printing. The viscosity of the curable resin tax article is within the range described above, whereby the deviations of openings from a design value are inhibited to inhibit occurrence of trouble when a large number of openings are disposed so that a large number of LEDs can be mounted in the substrate for mounting an LED according to the present invention.

The curable resin composition can be further blended with a component such as a thixotropic agent, an intimate contact promoter, a block copolymer, a chain transfer agent, a polymerization inhibitor, a copper inhibitor, an antioxidant, an antirust agent, a thickener such as organic bentonite or montmorillonite, at least any one of antifoaming and leveling agents based on silicone, fluorine, a polymer, or the like, a silane coupling agent based on imidazole, thiazole, triazole, or the like, or a flame retardant such as a phosphorus compound such as a phosphinate, a phosphate ester derivative, or a phosphazene compound, as needed, as well as the components described above. Components known in the field of electronic materials can be used as such components.

### [Method of Preparing Curable Resin Composition]

For preparation of the curable resin composition of the present invention, each component is weighed, blended, and then preliminarily stirred by a stirring machine. Subsequently, the preparation can be performed by dispersing and kneading each component by a kneading machine. Examples of the kneading machine described above may include bead mills, ball mills, sand mills, three-roll mills, and two-roll mills. A dispersion condition such as the speed ratio of each roll of such a three-roll mill can be appropriately set according to viscosity of interest.

### (Base Material)

A conventionally known base material for mounting an LED can be used as the base material used in the substrate for mounting an LED according to the present invention. Examples of the base material may include copper-clad laminates of all grades (such as FR-4) using materials such as copper-clad laminates for high-frequency circuits using paper phenol, paper epoxy, glass fabric epoxy, glass polyimide, glass fabric/nonwoven fabric epoxy, glass fabric/paper epoxy, synthetic fiber epoxy, fluorine resin/polyethylene/polyphenylene ether, polyphenylene oxide/cyanate, and the like, and, in addition, metal substrates, polyimide films, polyethylene terephthalate films, polyethylene naphthalate (PEN) films, glass substrates, ceramic substrates, and wafer plates, as well as printed wiring boards and flexible printed wiring boards on which circuits have been formed with copper and the like in advance.

The thickness of the base material is not particularly limited, and is preferably 3.0 mm or less, more preferably 2.0 mm or less, and still more preferably 1.0 mm or less, and preferably 0.1 mm or more, more preferably 0.2 mm or more, and still more preferably 0.5 mm or more.

When the thickness of the base material is within the range described above, the thickness of the entire LED-mounted substrate can be reduced while maintaining strength.

### [Method of Producing Substrate for Mounting LED]

In a method of producing the substrate for mounting an LED of the present invention, for example, the curable resin composition described above is adjusted to have a viscosity suitable for a coating method using the organic solvent described above, and is coated on the base material by a method such as a screen printing method, a flow coating method, a roll coating method, a blade coating method, or a bar coating method, and the organic solvent included in the composition is then subjected to volatilization drying (pre-drying) at a temperature of 60 to 100° C. for 15 to 90 minutes to form a tack-free reflective layer. In consideration of the troublesomeness of the production steps, the reflective layer is preferably formed by one-layer coating.

The volatilization drying performed after the coating of the curable resin composition described above on the base material can be performed using a circulating type hot-air drying oven, an IR oven, a hot plate, a convection oven, or the like (a method in which hot blast in a drying machine is subjected to countercurrent contact using an article including a heat source in an air heating manner by vapor, and a method in which the hot blast is sprayed on a support through a nozzle). For an apparatus, examples of the hot blast circulation drying oven include DF610 manufactured by Yamato Scientific Co., Ltd.

### [LED-Mounted Substrate]

An LED-mounted substrate of the present invention includes: the substrate for mounting an LED of the present invention; and LEDs mounted in the generally central regions of the openings of the substrate for mounting an LED. The drawings for the LED-mounted substrate are as described in [Substrate for Mounting LED] described above. In particular, the white reflective layer results in excellent reflectivity, and can be therefore preferably used for mounting an LED.

A method of producing an LED-mounted substrate is not particularly limited as long as the substrate for mounting an LED of the present invention is used. LEDs are mounted in the generally central regions of the openings of the substrate for mounting an LED by a conventionally known method.

### EXAMPLES

The present invention is described in more detail below with reference to Examples. However, the present invention is not limited to the following Examples.

### (Synthesis of Fluorine Resin Including Hydroxy Group)

A fluorine resin (copolymer of tetrafluoroethylene and vinyl acetate (molar ratio of tetrafluoroethylene and vinyl acetate=1/1)) was generated to obtain the fluorine resin including a hydroxy group, having a hydroxyl group having a hydroxyl group valence of 60 mg/g (KOH), by a known technique.

### (Preparation of Curable Resin Composition 1)

Mixing of 25.5 parts by mass of the fluorine resin including a hydroxy group, synthesized as described above, 6.98 parts by mass of chain block diisocyanate (trade name: E402-B80B, manufactured by Asahi Kasei Corp.), 59.4 parts by mass of rutile type titanium oxide (having an average particle diameter of 0.28 μm, trade name: CR-93, manufactured by ISHIHARA SANGYO KAISHA, LTD.), and 7.0 parts by mass of silica (having an average particle diameter of 0.1 μm, trade name: Nipsil E743, manufactured by TOSOH SILICA CORPORATION) was performed, and the mixture was stirred by a stirring machine, and then kneaded by a three-roll mill. Subsequently, carbitol acetate was blended as an organic solvent to prepare a thermosetting resin composition so that a solid content ratio was 78% by mass.

### (Preparation of Curable Resin Composition 2)

Mixing of 25.5 parts by mass of bisphenol A type epoxy resin (trade name: jER-825, manufactured by Mitsubishi Chemical Corporation), 5.6 parts by mass of chain block diisocyanate (based on silicate, trade name X-12-1159L, manufactured by Shin-Etsu Chemical Co., Ltd.), 59.4 parts by mass of rutile type titanium oxide (having an average particle diameter of 0.28 μm, trade name: CR-93, manufactured by ISHIHARA SANGYO KAISHA, LTD.), and 7.0 parts by mass of silica (having an average particle diameter of 0.1 μm, trade name: Nipsil E743, manufactured by TOSOH SILICA CORPORATION) was performed, and the mixture was stirred by a stirring machine, and then kneaded in a three-roll mill to prepare a thermosetting resin composition.

### (Preparation of Curable Resin Composition 3)

Mixing of 100 parts by mass of acrylate including a carboxyl group (trade name: Z250, manufactured by DAICEL-ALLNEX LTD.), 5 parts by mass of dipentaerythritol hexaacrylate (trade name: ARONIX MT-3549, manufactured by TOAGOSEI CO., LTD.), 100 parts by mass of rutile type titanium oxide (having an average particle diameter of 0.28 μm, trade name: CR-95, manufactured by ISHIHARA SANGYO KAISHA, LTD.), 3 parts by mass of a photopolymerization initiator (O-acetyl-1-[6-(2-methylbenzoyl)-9-ethyl-9H-carbazol-3-yllethanoneoxime, trade name: Irgacure OXE02, manufactured by BASF Japan Ltd.), and 10 parts by mass of an organic solvent (dipropylene glycol monomethyl ether acetate) were performed, and the mixture was stirred by a stirring machine, and then kneaded in a three-roll mill to prepare a photo-curable resin composition.

### (Preparation of Curable Resin Composition 4)

A thermosetting resin composition was prepared by similar preparation except that the chain blocked isocyanate (trade name: E402-B80B, manufactured by Asahi Kasei Corp.) in (Preparation of Curable Resin Composition 1) described above was changed to 10 parts by mass thereof.

### (Preparation of Curable Resin Composition 5)

A thermosetting resin composition was prepared by similar preparation except that chain blocked isocyanate (trade name: E402-B80B, manufactured by Asahi Kasei Corp.) in (Preparation of Curable Resin Composition 1) described above was changed to blocked isocyanate based on HDI trimmer (BI7982 manufactured by GSI Creos Corporation).

### (Preparation of Curable Resin Composition 6)

A thermosetting resin composition was prepared by similar preparation except that blocked isocyanate based on HDI trimmer (BI7951 manufactured by GSI Creos Corporation) in (Preparation of Curable Resin Composition 5) described above was changed to 10 parts by mass thereof.

### (Preparation of Curable Resin Composition 7)

A thermosetting resin composition was prepared by similar preparation except that chain blocked isocyanate (trade name: E402-B80B, manufactured by Asahi Kasei Corp.) in (Preparation of Curable Resin Composition 1) described above was changed to blocked isocyanate based on HDI biuret (BI7960 manufactured by GSI Creos Corporation).

### <Measurement Method>

### (Storage Elastic Modulus)

For the storage elastic modulus of a reflective layer (cured product) formed on a substrate as follows, a cured product was peeled from a base material to cut a piece of 5±0.3 mm×50+5 mm, measurement of the test piece was then performed by a dynamic viscoelasticity measurement apparatus (DMA, model number: RSA-G2, manufactured by TA Instruments Japan Inc.) under conditions of a measured temperature of 25 to 300° C., a temperature-raising rate of 5° C./min, a loading gap of 10 mm, a frequency of 1 Hz, and an axial force (axial tension) of 0.05 N, and the value of the storage elastic modulus at 25° C. in the measurement was regarded as the measured value.

### (Reflectance)

As the reflectance of the reflective layer (cured product) formed on the substrate as follows, the Y value in the XYZ color specification method was measured by an SCI method using a spectral colorimeter (model number: CM-2600d, manufactured by KONICA MINOLTA, INC.). The reflectance was evaluated based on the following criteria:
⊚: The reflectance was 90% or more.
C: The reflectance was 85% or more and less than 90%.
x: The reflectance was less than 85%.

### (Warpage)

The reflective layer was formed as follows, LEDs were mounted, and the total of the heights of the four corners of the substrate, rising from a desk, was then measured using a macrometer, and regarded as the warpage of the substrate. The warpage was evaluated based on the following criteria:

C: The warpage was less than 3 mm.

x: The warpage was 3 mm or more.

### (Intimate Contact Property)

The intimate contact property of the reflective layer (cured product) formed on the substrate described below can be determined by a crosscut test according to JISK5600-5-6. Each evaluation substrate was scratched so that 100 squares of 1 mm² were formed. Then, peeling off the resin layer was confirmed by a tape peel. The peeling rate in the crosscut test is the percentage of the area of “peeling” with respect to the area of all the squares. The area of “peeling” is the total of the areas of parts obtained by peeling off the reflective layer (cured product) in the lattices. The intimate contact property was evaluated based on the following criteria:
O: “Peeling rate” was 0% (no peeling).
x: “Peeling rate” was more than 0% and less than 5%.
   (Deviation from Designed Value)

The deviations of the reflective layer (cured product) formed on the substrate as follows from designed values were evaluated by the following method. First, the lengths of the openings in the longitudinal and lateral directions on the substrate were measured using a microscope (VHS-500 manufactured by KEYENCE CORPORATION) before the reflective layer (cured product) was formed on the substrate. Then, the reflective layer (cured product) was formed on the substrate as follows, the lengths of the formed openings in the longitudinal and lateral directions were similarly measured using the microscope (VHS-500 manufactured by KEYENCE CORPORATION), and the differences between the lengths and the lengths prior to the formation of the reflective layer (cured product) were calculated and regraded as deviations. On the basis of the calculated deviations, the deviations from the designed values were evaluated based on the following criteria:
O: Deviations were less than 0.2 mm and more than −0.2 mm, and there were no deviations from the designed values.
x: Deviations were 0.2 mm or more or −0.2 mm or less, and there were deviations from the designed values.

### Example 1

The curable resin composition 1 prepared as described above was coated on a glass plate having a thickness of 0.8 mm, a length of 100 mm, and a width of 200 mm, on which wiring and electrodes were formed, by screen printing so that openings for mounting LEDs were disposed. The curable resin composition 1 was thermally cured at 140° C. for 60 minutes to form the reflective layer having a thickness of 30 μm. The storage elastic modulus of the reflective layer (cured product of curable resin composition) at 25° C. was 3.4 GPa. The reflectance of the reflective layer was 91%. Further, the result of the crosscut test of the reflective layer was a peeling rate of 0% (no peeling).

The number of openings disposed on the substrate as described above was 300. The lengths of the openings were 1.0 mm in the longitudinal direction and 1.1 mm in the lateral direction, the deviations of the openings in each of the longitudinal and lateral directions were ±0.1 mm, and the openings were formed according to the designed values. The spacings between the openings and the openings adjacent thereto were 6.4 mm in the longitudinal direction and 6.0 mm in the lateral direction. An LED chip of 0.7 mm in the longitudinal direction and 0.8 mm in the lateral direction was mounted in the generally central region of each opening by solder. The measured warpage of a substrate end after the mounting was 0.2 mm.

In such a case, the total area is 20000 mm², the total area of the openings is 330 mm², the area of the reflective layer is 19670 mm², and the area of gaps is 162 mm². As a result, the total area rate of the openings with respect to the area of the reflective layer was 1.7%.

### Example 2

To the curable resin composition 1 (100 parts by mass) prepared as described above, 1 part by mass of dibutyl diglycol was added, and a curable resin composition having a dilution rate of 1% was obtained. The obtained curable resin composition was used and coated on a glass plate having a thickness of 0.8 mm, a length of 100 mm, and a width of 200 mm, on which wiring and electrodes were formed, by screen printing so that openings for mounting LEDs were disposed in a manner similar to that in Example 1. The curable resin composition was thermally cured at 140° C. for 60 minutes to form a reflective layer having a thickness of 30 μm. The storage elastic modulus of the reflective layer (cured product of curable resin composition) at 25° C. was 3.4 GPa. The reflectance of the reflective layer was 91%. Further, the result of the crosscut test of the reflective layer was a peeling rate of 0% (no peeling).

The number of openings disposed on the substrate as described above was 300. The lengths of the openings were 1.0 mm in the longitudinal direction and 1.1 mm in the lateral direction, the deviations of the openings in each of the longitudinal and lateral directions were ±0.1 mm, and the openings were formed according to the designed values. The spacings between the openings and the openings adjacent thereto were 6.4 mm in the longitudinal direction and 6.0 mm in the lateral direction. An LED chip of 0.7 mm in the longitudinal direction and 0.8 mm in the lateral direction was mounted in the generally central region of each opening by solder. The measured warpage of a substrate end after the mounting was 0.2 mm.

In such a case, the total area is 20000 mm², the total area of the openings is 330 mm², the area of the reflective layer is 19670 mm², and the area of gaps is 162 mm². As a result, the total area rate of the openings with respect to the area of the reflective layer was 1.7%.

### Example 3

The curable resin composition 1 prepared as described above was coated on a glass epoxy substrate having a thickness of 0.8 mm, a length of 100 mm, and a width of 200 mm, on which wiring and electrodes were formed, by screen printing so that openings for mounting LEDs were disposed. The curable resin composition 1 was thermally cured at 140° C. for 60 minutes to form a reflective layer having a thickness of 30 μm. The storage elastic modulus of the reflective layer (cured product of curable resin composition) at 25° C. was 3.4 GPa. The reflectance of the reflective layer was 91%. Further, the result of the crosscut test of the reflective layer was a peeling rate of 0% (no peeling).

The number of openings disposed on the substrate as described above was 300. The lengths of the openings were 1.0 mm in the longitudinal direction and 1.1 mm in the lateral direction, the deviations of the openings in each of the longitudinal and lateral directions were ±0.1 mm, and the openings were formed according to the designed values. The spacings between the openings and the openings adjacent thereto were 6.4 mm in the longitudinal direction and 6.0 mm in the lateral direction. An LED chip of 0.7 mm in the longitudinal direction and 0.8 mm in the lateral direction was mounted in the generally central region of each opening by solder. The measured warpage of a substrate end after the mounting was 0.2 mm.

In such a case, the total area is 20000 mm², the total area of the openings is 330 mm², the area of the reflective layer is 19670 mm², and the area of gaps is 162 mm². As a result, the total area rate of the openings with respect to the area of the reflective layer was 1.7%.

### Example 4

The curable resin composition 1 prepared as described above was coated on a glass plate having a thickness of 0.8 mm, a length of 100 mm, and a width of 200 mm, on which wiring and electrodes were formed, by screen printing so that openings for mounting LEDs were disposed. The curable resin composition 1 was thermally cured at 140° C. for 60 minutes to form the reflective layer having a thickness of 30 μm. The storage elastic modulus of the reflective layer (cured product of curable resin composition) at 25° C. was 3.4 GPa. The reflectance of the reflective layer was 87%. Further, the result of the crosscut test of the reflective layer was a peeling rate of 0% (no peeling).

The number of openings disposed on the substrate as described above was 2100. The lengths of the openings were 0.7 mm in the longitudinal direction and 0.8 mm in the lateral direction, the deviations of the openings in each of the longitudinal and lateral directions were ±0.1 mm, and the openings were formed according to the designed values. The spacings between the openings and the openings adjacent thereto were 2.1 mm in the longitudinal direction and 2.4 mm in the lateral direction. An LED chip of 0.4 mm in the longitudinal direction and 0.5 mm in the lateral direction was mounted in the generally central region of each opening by solder. The measured warpage of a substrate end after the mounting was 0.2 mm.

In such a case, the total area is 20000 mm², the total area of the openings is 1176 mm², the area of the reflective layer is 18824 mm², and the area of gaps is 756 mm². As a result, the total area rate of the openings with respect to the area of the reflective layer was 6.3%.

### Example 5

The curable resin composition 1 prepared as described above was coated on a glass epoxy substrate having a thickness of 0.8 mm, a length of 100 mm, and a width of 200 mm, on which wiring and electrodes were formed, by screen printing so that openings for mounting LEDs were disposed. The curable resin composition 1 was thermally cured at 140° C. for 30 minutes to form a reflective layer having a thickness of 30 μm. The storage elastic modulus of the reflective layer (cured product of curable resin composition) at 25° C. was 3.4 GPa. The reflectance of the reflective layer was 89%. Further, the result of the crosscut test of the reflective layer was a peeling rate of 0% (no peeling).

The number of openings disposed on the substrate as described above was 230. The lengths of the openings were 0.7 mm in the longitudinal direction and 0.8 mm in the lateral direction, the deviations of the openings in each of the longitudinal and lateral directions were #0.1 mm, and the openings were formed according to the designed values. The spacings between the openings and the openings adjacent thereto were 7.0 mm in the longitudinal direction and 8.0 mm in the lateral direction. An LED chip of 0.4 mm in the longitudinal direction and 0.5 mm in the lateral direction was mounted in the generally central region of each opening by solder. The measured warpage of a substrate end after the mounting was 0.2 mm.

In such a case, the total area is 20000 mm², the total area of the openings is 128.8 mm², the area of the reflective layer is 19871.2 mm², and the area of gaps is 82.8 mm². As a result, the total area rate of the openings with respect to the area of the reflective layer was 0.65%.

### Example 6

The curable resin composition 1 prepared as described above was coated on a glass epoxy substrate having a thickness of 0.8 mm, a length of 100 mm, and a width of 200 mm, on which wiring and electrodes were formed, by screen printing so that openings for mounting LEDs were disposed. The curable resin composition 1 was thermally cured at 140° C. for 30 minutes to form a reflective layer having a thickness of 30 μm. The storage elastic modulus of the reflective layer (cured product of curable resin composition) at 25° C. was 3.4 GPa. The reflectance of the reflective layer was 89%. Further, the result of the crosscut test of the reflective layer was a peeling rate of 0% (no peeling).

The number of openings disposed on the substrate as described above was 2800. The lengths of the openings were 0.7 mm in the longitudinal direction and 0.8 mm in the lateral direction, the deviations of the openings in each of the longitudinal and lateral directions were #0.1 mm, and the openings were formed according to the designed values. The spacings between the openings and the openings adjacent thereto were 1.5 mm in the longitudinal direction and 1.8 mm in the lateral direction. An LED chip of 0.4 mm in the longitudinal direction and 0.5 mm in the lateral direction was mounted in the generally central region of each opening by solder. The measured warpage of a substrate end after the mounting was 0.2 mm.

In such a case, the total area is 20000 mm², the total area of the openings is 1568 mm², the area of the reflective layer is 18432 mm², and the area of gaps is 1008 mm². As a result, the total area rate of the openings with respect to the area of the reflective layer was 8.5%.

### Example 7

The curable resin composition 1 prepared as described above was coated on a polyimide film having a thickness of 0.1 mm, a length of 100 mm, and a width of 200 mm, on which wiring and electrodes were formed, by screen printing so that openings for mounting LEDs were disposed. The curable resin composition 1 was thermally cured at 140° C. for 30 minutes to form a reflective layer having a thickness of 30 μm. The elastic modulus of the reflective layer (cured product of curable resin composition) at 25° C. was 3.4 GPa. The reflectance of the reflective layer was 89%. Further, the result of the crosscut test of the reflective layer was a peeling rate of 0% (no peeling).

The number of openings disposed on the substrate as described above was 2800. The lengths of the openings were 0.7 mm in the longitudinal direction and 0.8 mm in the lateral direction, the deviations of the openings in each of the longitudinal and lateral directions were ±0.1 mm, and the openings were formed according to the designed values. The spacings between the openings and the openings adjacent thereto were 1.5 mm in the longitudinal direction and 1.8 mm in the lateral direction. An LED chip of 0.4 mm in the longitudinal direction and 0.5 mm in the lateral direction was mounted in the generally central region of each opening by solder. The measured warpage of a substrate end after the mounting was 1.5 mm.

In such a case, the total area is 20000 mm², the total area of the openings is 1568 mm², the area of the reflective layer is 18432 mm², and the area of gaps is 1008 mm². As a result, the total area rate of the openings with respect to the area of the reflective layer was 8.5%.

### Example 8

The curable resin composition 4 prepared as described above was coated on a glass plate having a thickness of 0.8 mm, a length of 100 mm, and a width of 200 mm, on which wiring and electrodes were formed, by screen printing so that openings for mounting LEDs were disposed. The curable resin composition 4 was thermally cured at 140° C. for 60 minutes to form the reflective layer having a thickness of 30 μm. The storage elastic modulus of the reflective layer (cured product of curable resin composition) at 25° C. was 2.8 GPa. The reflectance of the reflective layer was 91%. Further, the result of the crosscut test of the reflective layer was a peeling rate of 0% (no peeling).

The number of openings disposed on the substrate as described above was 300. The lengths of the openings were 1.0 mm in the longitudinal direction and 1.1 mm in the lateral direction, the deviations of the openings in each of the longitudinal and lateral directions were #0.1 mm, and the openings were formed according to the designed values. The spacings between the openings and the openings adjacent thereto were 6.4 mm in the longitudinal direction and 6.0 mm in the lateral direction. An LED chip of 0.7 mm in the longitudinal direction and 0.8 mm in the lateral direction was mounted in the generally central region of each opening by solder. The measured warpage of a substrate end after the mounting was 0.2 mm.

In such a case, the total area is 20000 mm², the total area of the openings is 330 mm², the area of the reflective layer is 19670 mm², and the area of gaps is 162 mm². As a result, the total area rate of the openings with respect to the area of the reflective layer was 1.7%.

### Example 9

The curable resin composition 5 prepared as described above was coated on a glass plate having a thickness of 0.8 mm, a length of 100 mm, and a width of 200 mm, on which wiring and electrodes were formed, by screen printing so that openings for mounting LEDs were disposed. The curable resin composition 5 was thermally cured at 140° C. for 60 minutes to form the reflective layer having a thickness of 30 μm. The storage elastic modulus of the reflective layer (cured product of curable resin composition) at 25° C. was 2.4 GPa. The reflectance of the reflective layer was 91%. Further, the result of the crosscut test of the reflective layer was a peeling rate of 0% (no peeling).

The number of openings disposed on the substrate as described above was 300. The lengths of the openings were 1.0 mm in the longitudinal direction and 1.1 mm in the lateral direction, the deviations of the openings in each of the longitudinal and lateral directions were ±0.1 mm, and the openings were formed according to the designed values. The spacings between the openings and the openings adjacent thereto were 6.4 mm in the longitudinal direction and 6.0 mm in the lateral direction. An LED chip of 0.7 mm in the longitudinal direction and 0.8 mm in the lateral direction was mounted in the generally central region of each opening by solder. The measured warpage of a substrate end after the mounting was 0.2 mm.

In such a case, the total area is 20000 mm², the total area of the openings is 330 mm², the area of the reflective layer is 19670 mm², and the area of gaps is 162 mm². As a result, the total area rate of the openings with respect to the area of the reflective layer was 1.7%.

### Example 10

The curable resin composition 6 prepared as described above was coated on a glass plate having a thickness of 0.8 mm, a length of 100 mm, and a width of 200 mm, on which wiring and electrodes were formed, by screen printing so that openings for mounting LEDs were disposed. The curable resin composition 6 was thermally cured at 140° C. for 60 minutes to form the reflective layer having a thickness of 30 μm. The storage elastic modulus of the reflective layer (cured product of curable resin composition) at 25° C. was 3.6 GPa. The reflectance of the reflective layer was 91%. Further, the result of the crosscut test of the reflective layer was a peeling rate of 0% (no peeling).

The number of openings disposed on the substrate as described above was 300. The lengths of the openings were 1.0 mm in the longitudinal direction and 1.1 mm in the lateral direction, the deviations of the openings in each of the longitudinal and lateral directions were ±0.1 mm, and the openings were formed according to the designed values. The spacings between the openings and the openings adjacent thereto were 6.4 mm in the longitudinal direction and 6.0 mm in the lateral direction. An LED chip of 0.7 mm in the longitudinal direction and 0.8 mm in the lateral direction was mounted in the generally central region of each opening by solder. The measured warpage of a substrate end after the mounting was 0.2 mm.

In such a case, the total area is 20000 mm², the total area of the openings is 330 mm², the area of the reflective layer is 19670 mm², and the area of gaps is 162 mm². As a result, the total area rate of the openings with respect to the area of the reflective layer was 1.7%.

### Example 11

The curable resin composition 7 prepared as described above was coated on a glass plate having a thickness of 0.8 mm, a length of 100 mm, and a width of 200 mm, on which wiring and electrodes were formed, by screen printing so that openings for mounting LEDs were disposed. The curable resin composition 7 was thermally cured at 140° C. for 60 minutes to form the reflective layer having a thickness of 30 μm. The storage elastic modulus of the reflective layer (cured product of curable resin composition) at 25° C. was 1.5 GPa. The reflectance of the reflective layer was 91%. Further, the result of the crosscut test of the reflective layer was a peeling rate of 0% (no peeling).

The number of openings disposed on the substrate as described above was 300. The lengths of the openings were 1.0 mm in the longitudinal direction and 1.1 mm in the lateral direction, the deviations of the openings in each of the longitudinal and lateral directions were ±0.1 mm, and the openings were formed according to the designed values. The spacings between the openings and the openings adjacent thereto were 6.4 mm in the longitudinal direction and 6.0 mm in the lateral direction. An LED chip of 0.7 mm in the longitudinal direction and 0.8 mm in the lateral direction was mounted in the generally central region of each opening by solder. The measured warpage of a substrate end after the mounting was 0.2 mm.

In such a case, the total area is 20000 mm², the total area of the openings is 330 mm², the area of the reflective layer is 19670 mm², and the area of gaps is 162 mm². As a result, the total area rate of the openings with respect to the area of the reflective layer was 1.7%.

### Comparative Example 1

The curable resin composition 1 prepared as described above was coated on a glass epoxy substrate having a thickness of 0.8 mm, a length of 100 mm, and a width of 200 mm, on which wiring and electrodes were formed, by screen printing so that openings for mounting LEDs were disposed. The curable resin composition 1 was thermally cured at 140° C. for 30 minutes to form a reflective layer having a thickness of 30 μm. The elastic modulus of the reflective layer (cured product of curable resin composition) at 25° C. was 0.8 GPa. The reflectance of the reflective layer was 90%. Further, the result of the crosscut test of the reflective layer was a peeling rate of 0% (no peeling).

The number of openings disposed on the substrate as described above was 3150. The lengths of the openings were 0.7 mm in the longitudinal direction and 0.8 mm in the lateral direction. The spacings between the openings and the openings adjacent thereto were 1.2 mm in the longitudinal direction and 1.4 mm in the lateral direction, and were less than twice the lengths of the openings. The deviations of the openings in each of the longitudinal and lateral directions were 0.4 mm or more or −0.4 mm or less. When the spacings between the openings and the openings adjacent thereto were small, the deviations of the openings were increased, and the openings were unable to be formed according to the designed values. When an LED chip of 0.4 mm in the longitudinal direction and 0.5 mm in the lateral direction was mounted in the generally central region of each opening, deviations generated by openings were greater than spacings between the openings and LEDs, the LEDs were unable to be mounted in the openings, and it was impossible to measure warpage.

It was impossible to calculate the total area of the openings, the area of the reflective layer, and the total area rate of the openings with respect to the area of the reflective layer.

### Comparative Example 2

The curable resin composition 2 prepared as described above was coated on a glass epoxy substrate having a thickness of 0.8 mm, a length of 100 mm, and a width of 200 mm, on which wiring and electrodes were formed, by screen printing so that openings for mounting LEDs were disposed. The curable resin composition 2 was thermally cured at 150° C. for 60 minutes to form a reflective layer having a thickness of 30 μm. The elastic modulus of the reflective layer (cured product of curable resin composition) at 25° C. was 6.8 GPa. The reflectance of the reflective layer was 87%. Further, the result of the crosscut test of the reflective layer was a peeling rate of 2%.

The number of openings disposed on the substrate as described above was 2100. The lengths of the openings were 0.7 mm in the longitudinal direction and 0.8 mm in the lateral direction, the deviations of the openings in each of the longitudinal and lateral directions were #0.1 mm, and the openings were formed according to the designed values. The spacings between the openings and the openings adjacent thereto were 2.1 mm in the longitudinal direction and 2.4 mm in the lateral direction. An LED chip of 0.4 mm in the longitudinal direction and 0.5 mm in the lateral direction was mounted in the generally central region of each opening by solder. However, the measured warpage of a substrate end after the mounting was 4.2 mm.

In such a case, the total area is 20000 mm², the total area of the openings is 1176 mm², the area of the reflective layer is 18824 mm², and the area of gaps is 756 mm². As a result, the total area rate of the openings with respect to the area of the reflective layer was 6.3%.

### Comparative Example 3

The curable resin composition 1 prepared as described above was coated on a glass epoxy substrate having a thickness of 0.8 mm, a length of 100 mm, and a width of 200 mm, on which wiring and electrodes were formed, by screen printing so that openings for mounting LEDs were disposed. The curable resin composition 1 was thermally cured at 140° C. for 30 minutes to form a reflective layer having a thickness of 30 μm. The elastic modulus of the reflective layer (cured product of curable resin composition) at 25° C. was 0.8 GPa. The reflectance of the reflective layer was 90%. Further, the result of the crosscut test of the reflective layer was a peeling rate of 0% (no peeling).

The number of openings disposed on the substrate as described above was 3150. The lengths of the openings were 1.4 mm in the longitudinal direction and 1.6 mm in the lateral direction. The spacings between the openings and the openings adjacent thereto were 0.5 mm in the longitudinal direction and 0.6 mm in the lateral direction, and were less than the lengths of the openings. The deviations of the openings in each of the longitudinal and lateral directions were 0.4 mm or more or −0.4 mm or less. When the spacings between the openings and the openings adjacent thereto in the longitudinal and lateral directions were less than the length of the lengths of the openings in the longitudinal and lateral directions, respectively, the deviations of the openings were increased, and the openings were unable to be formed according to the designed values. As a result, the LEDs were unable to be mounted in the openings, and it was impossible to measure warpage.

It was impossible to calculate the total area of the openings, the area of the reflective layer, and the total area rate of the openings with respect to the area of the reflective layer.

### Comparative Example 4

The curable resin composition 3 prepared as described above was coated on a glass epoxy substrate having a thickness of 0.8 mm, a length of 100 mm, and a width of 200 mm, on which wiring and electrodes were formed, by screen printing so that openings for mounting LEDs were disposed. The curable resin composition 3 was irradiated at 1000 mJ using a UV exposure machine to form a reflective layer having a thickness of 30 μm. The storage elastic modulus of the reflective layer (cured product of curable resin composition) at 25° C. was 5.6 GPa. The reflectance of the reflective layer was 86%. Further, the result of the crosscut test of the reflective layer was a peeling rate of 0% (no peeling).

The number of openings disposed on the substrate as described above was 2800. The lengths of the openings were 0.7 mm in the longitudinal direction and 0.8 mm in the lateral direction, the deviations of the openings in each of the longitudinal and lateral directions were ±0.1 mm, and the openings were formed according to the designed values. The spacings between the openings and the openings adjacent thereto were 1.5 mm in the longitudinal direction and 1.8 mm in the lateral direction. An LED chip of 0.4 mm in the longitudinal direction and 0.5 mm in the lateral direction was mounted in the generally central region of each opening by solder. However, the measured warpage of a substrate end after the mounting was 3.5 mm.

In such a case, the total area is 20000 mm², the total area of the openings is 1568 mm², the area of the reflective layer is 18432 mm², and the area of gaps is 1008 mm². As a result, the total area rate of the openings with respect to the area of the reflective layer was 8.5%.

### Comparative Example 5

To the curable resin composition 1 (100 parts by mass) prepared as described above, 4 parts by mass of dibutyl diglycol was added, and a curable resin composition having a dilution rate of 4% was obtained. The obtained curable resin composition was used and coated on a glass plate having a thickness of 0.8 mm, a length of 100 mm, and a width of 200 mm, on which wiring and electrodes were formed, by screen printing so that openings for mounting LEDs were disposed in a manner similar to that in Example 1. The curable resin composition was thermally cured at 140° C. for 60 minutes to form a reflective layer having a thickness of 30 μm. The storage elastic modulus of the reflective layer (cured product of curable resin composition 1) at 25° C. was 0.8 GPa. The reflectance of the reflective layer was 90%. Further, the result of the crosscut test of the reflective layer was a peeling rate of 0% (no peeling).

The number of openings disposed on the substrate as described above was 300. The lengths of the openings were 1.0 mm in the longitudinal direction and 1.1 mm in the lateral direction, the deviations of the openings in each of the longitudinal and lateral directions were 0.2 mm or more or −0.2 mm or less, and it was impossible to form the openings according to the designed values. The spacings between the openings and the openings adjacent thereto were 6.4 mm in the longitudinal direction and 6.0 mm in the lateral direction. When a dilution rate was 4%, the deviations of the openings were increased, whereby the LEDs were unable to be mounted in the openings, and it was impossible to measure warpage.

It was impossible to calculate the total area of the openings, the area of the reflective layer, and the total area rate of the openings with respect to the area of the reflective layer.

### Comparative Example 6

The curable resin composition 1 prepared as described above was coated on a glass epoxy substrate having a thickness of 0.8 mm, a length of 100 mm, and a width of 200 mm, on which wiring and electrodes were formed, by screen printing so that openings for mounting LEDs were disposed. The curable resin composition 1 was thermally cured at 140° C. for 30 minutes to form a reflective layer having a thickness of 30 μm. The elastic modulus of the reflective layer (cured product of curable resin composition) at 25° C. was 0.8 GPa. The reflectance of the reflective layer was 84%. Further, the result of the crosscut test of the reflective layer was a peeling rate of 0% (no peeling).

The number of openings disposed on the substrate as described above was 2800. The lengths of the openings were 0.8 mm in the longitudinal direction and 0.9 mm in the lateral direction, the deviations of the openings in each of the longitudinal and lateral directions were ±0.1 mm, and the openings were formed according to the designed values. The spacings between the openings and the openings adjacent thereto were 1.7 mm in the longitudinal direction and 1.9 mm in the lateral direction. An LED chip of 0.4 mm in the longitudinal direction and 0.5 mm in the lateral direction was mounted in the generally central region of each opening by solder. The measured warpage of a substrate end after the mounting was 0.2 mm.

In such a case, the total area is 20000 mm², the total area of the openings is 2016 mm², the area of the reflective layer is 17984 mm², and the area of gaps is 1,456 mm². As a result, the total area rate of the openings with respect to the area of the reflective layer was 11.2%.

The substrates for mounting LEDs, produced in Examples 1 to 11 and Comparative Examples 1 to 6 as described above, are collectively set forth in the following Tables 1 to 3.

TABLE 1

| | Example 1 | Example 2 | Example 3 | Example 4 | Example 5 | Example 6 | Example 7 |
|---|---|---|---|---|---|---|---|
| Substrate | Glass | Glass | Glass | Glass | Glass | Glass | Polyimide |
| | | | | | epoxy | epoxy | |
| Curable resin composition | 1 | 1*¹ | 1 | 1 | 1 | 1 | 1 |
| Storage elastic modulus (GPa) | 3.4 | 3.4 | 3.4 | 3.4 | 3.4 | 3.4 | 3.4 |
| of cured product | | | | | | | |
| Length (mm) of opening in | 1.0 | 1.0 | 1.0 | 0.7 | 0.7 | 0.7 | 0.7 |
| longitudinal direction | | | | | | | |
| Length (mm) of opening in | 1.1 | 1.1 | 1.1 | 0.8 | 0.8 | 0.8 | 0.8 |
| lateral direction | | | | | | | |
| Spacing (mm) between | 6.4 | 6.4 | 6.4 | 2.1 | 7.0 | 1.5 | 1.5 |
| opening and opening adjacent | | | | | | | |
| thereto in longitudinal direction | | | | | | | |
| Spacing (mm) between | 6.0 | 6.0 | 6.0 | 2.4 | 8.0 | 1.8 | 1.8 |
| opening and opening adjacent | | | | | | | |
| thereto in lateral direction | | | | | | | |
| Total area rate (%) of openings | 1.7 | 1.7 | 1.7 | 6.3 | 0.65 | 8.5 | 8.5 |
| Deviation (mm) of opening in | ±0.1 | ±0.1 | ±0.1 | ±0.1 | ±0.1 | ±0.1 | ±0.1 |
| longitudinal direction | | | | | | | |
| Deviation (mm) of opening in | ±0.1 | ±0.1 | ±0.1 | ±0.1 | ±0.1 | ±0.1 | ±0.1 |
| lateral direction | | | | | | | |
| Reflectance | ⊚ | ⊚ | ⊚ | ◯ | ◯ | ◯ | ◯ |
| Warpage of substrate | ◯ | ◯ | ◯ | ◯ | ◯ | ◯ | ◯ |
| Intimate contact property | ◯ | ◯ | ◯ | ◯ | ◯ | ◯ | ◯ |
| Deviation from designed value | ◯ | ◯ | ◯ | ◯ | ◯ | ◯ | ◯ |

*¹Curable resin composition 1 diluted with 1% of dibutyl diglycol

TABLE 2

| | Example 8 | Example 9 | Example 10 | Example 11 |
|---|---|---|---|---|
| Substrate | Glass | Glass | Glass | Glass |
| Curable resin composition | 4 | 5 | 6 | 7 |
| Storage elastic modulus (GPa) of cured | 2.8 | 2.4 | 3.6 | 1.5 |
| product | | | | |
| Length (mm) of opening in longitudinal | 1.0 | 1.0 | 1.0 | 1.0 |
| direction | | | | |
| Length (mm) of opening in lateral | 1.1 | 1.1 | 1.1 | 1.1 |
| direction | | | | |
| Spacing (mm) between opening and | 6.4 | 6.4 | 6.4 | 6.4 |
| opening adjacent thereto in longitudinal | | | | |
| direction | | | | |
| Spacing (mm) between opening and | 6.0 | 6.0 | 6.0 | 6.0 |
| opening adjacent thereto in lateral | | | | |
| direction | | | | |
| Total area rate (%) of openings | 1.7 | 1.7 | 1.7 | 1.7 |
| Deviation (mm) of opening in | ±0.1 | ±0.1 | ±0.1 | ±0.1 |
| longitudinal direction | | | | |
| Deviation (mm) of opening in lateral | ±0.1 | ±0.1 | ±0.1 | ±0.1 |
| direction | | | | |
| Reflectance | ⊚ | ⊚ | ⊚ | ⊚ |
| Warpage of substrate | ◯ | ◯ | ◯ | ◯ |
| Intimate contact property | ◯ | ◯ | ◯ | ◯ |
| Deviation from designed value | ◯ | ◯ | ◯ | ◯ |

TABLE 3

| | Comparative | Comparative | Comparative | Comparative | Comparative | Comparative |
|---|---|---|---|---|---|---|
| | Example 1 | Example 2 | Example 3 | Example 4 | Example 5 | Example 6 |
| Substrate | Glass epoxy | Glass epoxy | Glass epoxy | Glass epoxy | Glass | Glass epoxy |
| Curable resin composition | 1 | 2 | 1 | 3 | 1*² | 1 |
| Storage elastic modulus (GPa) | 0.8 | 6.8 | 0.8 | 5.6 | 0.8 | 0.8 |
| of cured product | | | | | | |
| Length (mm) of opening in | 0.7 | 0.7 | 1.4 | 0.7 | 1.0 | 0.8 |
| longitudinal direction | | | | | | |
| Length (mm) of opening in | 0.8 | 0.8 | 1.6 | 0.8 | 1.1 | 0.9 |
| lateral direction | | | | | | |
| Spacing (mm) between opening | 1.2 | 2.1 | 0.5 | 1.5 | 6.4 | 1.7 |
| and opening adjacent thereto in | | | | | | |
| longitudinal direction | | | | | | |
| Spacing (mm) between opening | 1.4 | 2.4 | 0.6 | 1.8 | 6.0 | 1.9 |
| and opening adjacent thereto in | | | | | | |
| lateral direction | | | | | | |
| Total area rate (%) of openings | —*³ | 6.3 | —*³ | 8.5 | —*³ | 11.2 |
| Deviation (mm) of opening in | ≥0.4 | ±0.1 | ≥0.4 | ±0.1 | ≥0.2 | ±0.1 |
| longitudinal direction | or ≤−0.4 | | or ≤−0.4 | | or ≤−0.2 | |
| Deviation (mm) of opening in | ≥0.4 | ±0.1 | ≥0.4 | ±0.1 | ≥0.2 | ±0.1 |
| lateral direction | or ≤−0.4 | | or ≤−0.4 | | or ≤−0.2 | |
| Reflectance | ⊚ | ◯ | ⊚ | ◯ | ⊚ | X |
| Warpage of substrate | —*⁴ | X | —*⁴ | X | —*⁴ | ◯ |
| Intimate contact property | ◯ | X | ◯ | ◯ | ◯ | ◯ |
| Deviation from designed value | X | ◯ | X | ◯ | X | ◯ |

*²Curable resin composition 1 diluted with 4% of dibutyl diglycol
*³The increased deviation of openings precluded calculation.
*⁴Impossible mounting of LEDs precluded measurement.

1. A substrate for mounting an LED, the substrate comprising a base material and a reflective layer that is layered on an upper region thereof, wherein
a plurality of openings are disposed at generally equal spacings in longitudinal and lateral directions in the reflective layer, respectively,
the reflective layer is a cured product of a curable resin composition comprising a curable resin and titanium oxide,
the cured product has a storage elastic modulus of 4.0 GPa or less at 25° C.,
the spacings between the opening and the opening adjacent thereto in the longitudinal direction and the lateral direction are not less than twice the lengths of the opening in the longitudinal direction and the lateral direction, respectively, and
a total area rate of the openings with respect to an area of the reflective layer is 0.1% or more and 9.0% or less.

2. The substrate for mounting an LED according to claim 1, wherein the lengths of the openings of the reflective layer are 3.0 mm or less in the longitudinal direction and 4.0 mm or less in the lateral direction.

3. The substrate for mounting an LED according to claim 1, wherein the lengths of the openings of the reflective layer are 1.5 mm or less in the longitudinal direction and 1.5 mm or less in the lateral direction.

4. The substrate for mounting an LED according to claim 1, wherein the base material has a thickness of 3.0 mm or less.

5. The substrate for mounting an LED according to claim 1, wherein the base material has a thickness of 1.0 mm or less.

6. The substrate for mounting an LED according to claim 1, wherein a designed value of each of the openings has a deviation of less than 0.2 mm and more than −0.2 mm.

7. The substrate for mounting an LED according to claim 1, wherein the spacings between the opening and the opening adjacent thereto in the longitudinal direction and the lateral direction are not less than four times the lengths of the opening in the longitudinal direction and the lateral direction, respectively.

8. An LED-mounted substrate comprising LEDs mounted in generally central regions of the openings of the substrate for mounting an LED according to claim 1.
